(19) United States
(12) Patent Application Publication
(10) Pub. No.: US 2010/0266960 A1
(43) Pub. Date: Oct. 21, 2010

(54) METHOD OF MANUFACTURING SEMICONDUCTOR DEVICE AND EXPOSURE DEVICE

(76) Inventors: Hiromitsu MASHITA, Tokyo (JP); Toshiya KOTANI, Tokyo (JP); Michiya TAKIMOTO, Kanagawa (JP); Hidefumi MUKAI, Kanagawa (JP); Takafumi TAGUCHI, Kanagawa (JP); Kazuya FUKUHARA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/721,310

(22) Filed: Mar. 10, 2010

(30) Foreign Application Priority Data
Apr. 17, 2009 (JP) 2009-100545

(51) Int. Cl. G03F 7/20; G03B 27/42

(52) U.S. Cl. 430/312; 355/53

(57) ABSTRACT

A method of manufacturing a semiconductor device according to an embodiment includes determining a second exposure parameter including exposure parameters except for an exposure amount from a dimension distribution information so that a resist pattern of a first resist pattern formed based on a second pattern has a desired dimension in a plurality of regions to be shot within a surface of a wafer.

### CROSS-REFERENCE TO RELATED APPLICATIONS

This application is based upon and claims the benefit of priority from prior Japanese Patent Application No. 2009-100545, filed on Apr. 17, 2009 the entire contents of which are incorporated herein by reference.

### BACKGROUND

As a conventional technique, a method of predicting quantity of exposure is known, the method including a step of measuring a mask actual measurement of a mask pattern, a step of projecting an image of the mask pattern on a resist film with an examination light exposure so as to form a resist pattern, a step of measuring a projection actual measurement of the resist pattern, a step of carrying out a simulation of a standard exposure amount for projecting an image of the mask pattern of the mask actual measurement so as to obtain the projection actual measurement, a step of carrying out a simulation of a design light exposure for projecting an image of the mask pattern of the mask actual measurement so as to obtain the resist pattern of a designed value, and a step of calculating an amendment light exposure used for projection of an image of the mask pattern, obtained by multiplying the design light exposure by the examination light exposure and being divided by the standard exposure amount. The technique is, for example, disclosed in JP-A-2007-141949.

According to the method of predicting quantity of exposure, an amendment light exposure can be calculated, that is capable of forming a resist pattern having a line width equal to a designed value, even if a line width of mask pattern has a manufacturing error.

However, according to the conventional method of predicting quantity of exposure, variation in dimension within the surface of the wafer is caused due to a processing carried out for forming a resist pattern, so that it is difficult to obtain a resist pattern having a line width equal to a designed value only by adjusting the quality of exposure.

### BRIEF SUMMARY

A method of manufacturing a semiconductor device according to an embodiment includes carrying out a plurality of shots to a resist film formed on a wafer by using a first exposure parameter, wherein a first pattern and a second pattern having a dimension larger than the first pattern are used as an exposure subject of one shot, carrying out a processing of the resist film by using a processing condition that a resist pattern formed based on the first pattern has a desired dimension when the resist film is fabricated, so as to form a first resist pattern, measuring a dimension of a resist pattern of the first resist pattern, the resist pattern being formed based on the second pattern, so as to prepare dimension distribution information within a surface of the wafer, determining a second exposure parameter including exposure parameters except for an exposure amount from the dimension distribution information so that the resist pattern of the first resist pattern formed based on the second pattern has a desired dimension in a plurality of regions to be shot within the surface of the wafer, carrying out a plurality of shots to the resist film formed onto the wafer by using a second exposure parameter, wherein the first pattern and the second pattern are used as the exposure subject of one shot and fabricating the resist film under the processing condition so as to form a second resist pattern.

An exposure device according to another embodiment includes an exposure parameter determination part for determining a second exposure parameter including exposure parameters except for an exposure amount, wherein the exposure parameter determination part has the functions of carrying out a plurality of shots to a resist film formed on a wafer by using a first exposure parameter, wherein a first pattern and a second pattern having a dimension larger than the first pattern are used as an exposure subject of one shot, carrying out a processing of the resist film by using a processing condition that a resist pattern formed based on the first pattern has a desired dimension when the resist film is fabricated, so as to form a first resist pattern, measuring a dimension of a resist pattern of the first resist pattern, the resist pattern being formed based on the second pattern, so as to prepare dimension distribution information within a surface of the wafer, and determining a second exposure parameter including exposure parameters except for an exposure amount from the dimension distribution information so that the resist pattern of the first resist pattern formed based on the second pattern has a desired dimension in a plurality of regions to be shot within the surface of the wafer.

### BRIEF DESCRIPTION OF THE DRAWING

FIG. 1 is an explanatory view schematically showing a substrate processing system used in a first embodiment of the invention;

FIGS. 2A and 2B are top views schematically showing an aperture diaphragm used in the first embodiment of the invention;

FIG. 3 is an explanatory view schematically showing a wafer used in the first embodiment of the invention;

FIG. 4 is an explanatory view schematically showing a dimension distribution of a peripheral circuit pattern in the wafer used in the first embodiment of the invention;

FIGS. 5A and 5B are explanatory views schematically showing an evaluation pattern used in the first embodiment of the invention;

FIG. 6A is an explanatory view schematically showing a state of light exposure by an exposure device according to the first embodiment of the invention;

FIG. 6B is an explanatory view schematically showing a state of simulation by a control device used in the first embodiment of the invention;

FIG. 7 is an explanatory view schematically showing a condition of light exposure used in the first embodiment of the invention;

FIG. 8 is a flowchart schematically showing a method of manufacturing a semiconductor device according to the first embodiment of the invention;

FIG. 9 is a flowchart schematically showing a method of manufacturing a semiconductor device according to a second embodiment of the invention;

FIG. 10A is an explanatory view schematically showing a dimension distribution with respect to each light exposure shot used in a third embodiment of the invention;

FIG. 10B is a graph schematically showing a dimension difference ΔCD of the light exposure shot passing through a region indicated by an arrowed line in FIG. 10A; and

FIG. 11 is a flowchart schematically showing a method of manufacturing a semiconductor device according to the third embodiment of the invention.

### DETAILED DESCRIPTION

### First Embodiment

### Composition of Substrate Processing System

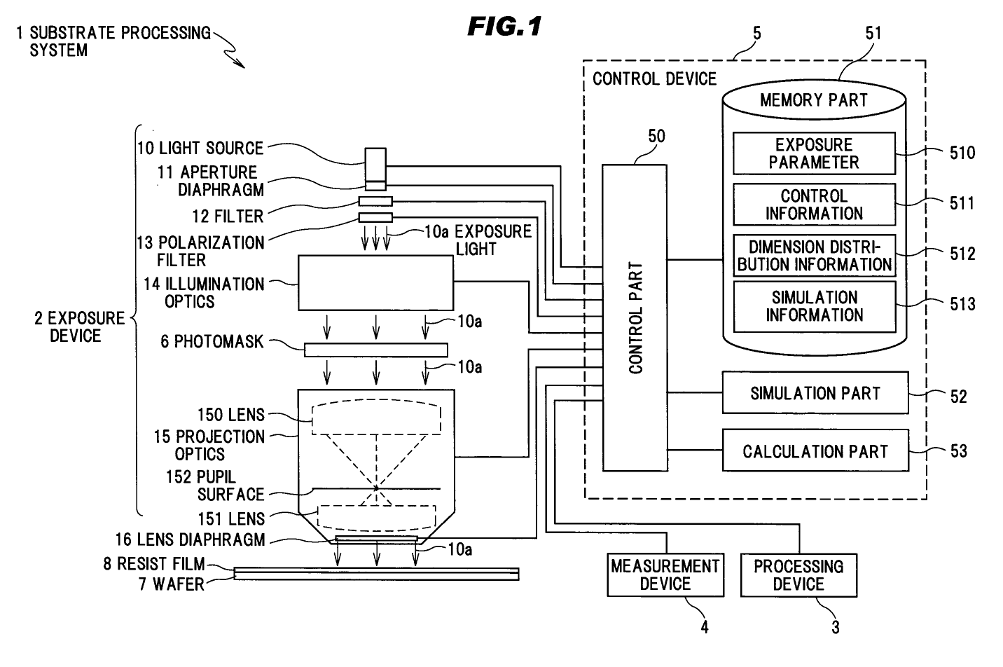

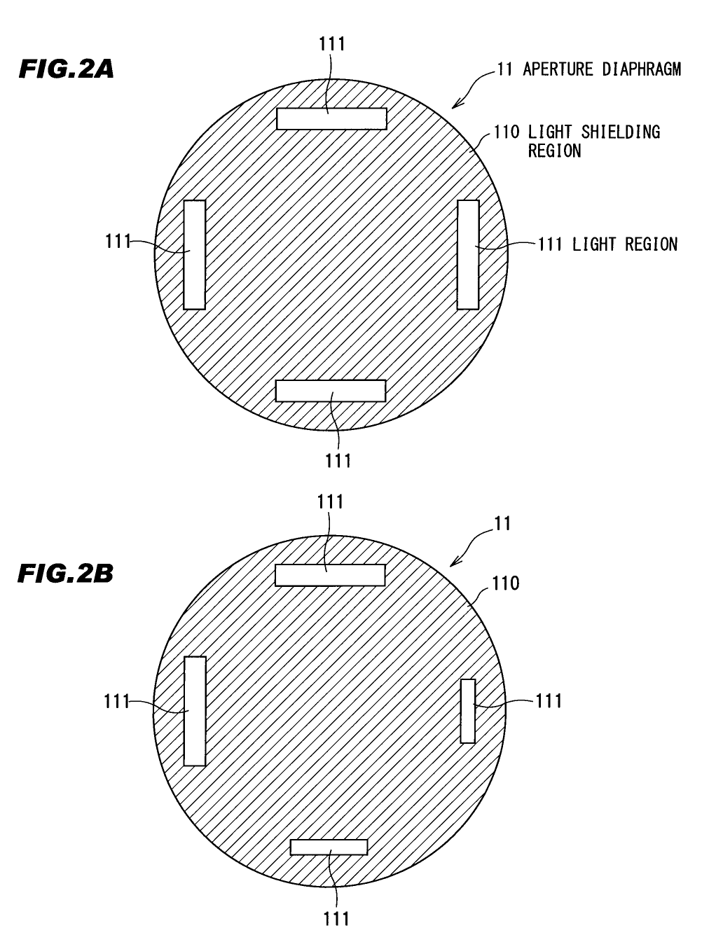

FIG. 1 is an explanatory view schematically showing a substrate processing system used in a first embodiment of the invention, and FIGS. 2A and 2B are top views schematically showing an aperture diaphragm used in the first embodiment of the invention.

The substrate processing system 1 is configured so as to mainly include an exposure device 2 having a control device 5, a processing device 3 and a measurement device 4.

The exposure device 2 is used for reducing and projecting a mask pattern formed onto a photomask 6 on a resist film 8 located on a wafer 7 by an exposure light 10a.

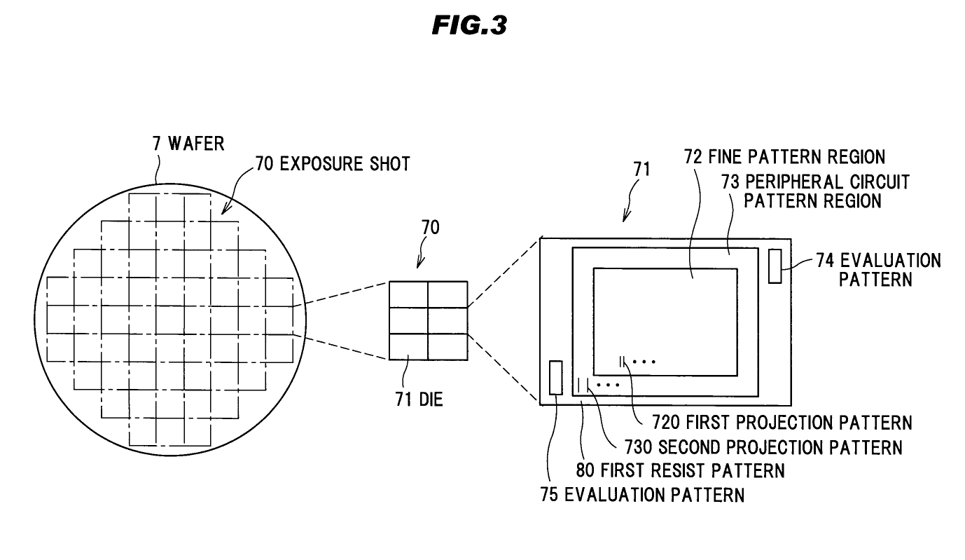

The exposure device 2 includes a simulation part 52 as an exposure parameter determination part for determining a second exposure parameter including exposure parameters except for an exposure amount, wherein the simulation part 52 has the functions of carrying out a plurality of shots to a resist film 8 formed on a wafer 7 by using a first exposure parameter, wherein a first pattern and a second pattern having a dimension larger than the first pattern are used as an exposure subject of one shot, carrying out a processing of the resist film 8 by using a processing condition that a resist pattern (a first projection pattern described below shown in FIG. 3) formed based on the first pattern has a predetermined dimension when the resist film is fabricated, so as to form a first resist pattern, measuring a dimension of a resist pattern of the first resist pattern, the resist pattern (a second projection pattern described below shown in FIG. 3) being formed based on the second pattern, so as to prepare dimension distribution information 512 within a surface of the wafer 7, and determining a second exposure parameter including exposure parameters except for an exposure amount from the dimension distribution information 512 so that the resist pattern of the first resist pattern formed based on the second pattern has a predetermined dimension in a plurality of regions to be shot within a surface of the wafer 7.

Also, as shown in FIG. 1, the exposure device 2 is roughly configured so as to include a light source 10. an aperture diaphragm 11, a filter 12, a polarization filter 13, an illumination optics 14, a projection optics 15, and a lens diaphragm 16.

The light source 10 is configured so as to emit, for example, ArF excimer laser, KrF excimer laser or the like as the exposure light 10a.

As shown in FIGS. 2A to 2B, the aperture diaphragm 11 includes, for example, a light shielding region 110 and light regions 111. The light shielding region 110 is a region for shielding the exposure light 10a emitted from the light source 10, and the light regions 111 is a region for transmitting the exposure light 10a emitted from the light source 10, and a shape of light can be changed according to a shape of the light regions 111. Further, the light regions 111 shown in FIGS. 2A to 2B are located aside from centers of light axes, but not limited to this, they can be also located at the centers of light axes. Further, the shape of light regions 111 is not limited to a rectangular shape, but it can be freely changed corresponding to the shape of light required.

The filter 12 is used for changing a brightness distribution of the exposure light 10a emitted via the light source 10 and the aperture diaphragm 11.

The polarization filter 13 is used for aligning an amplitude direction of the exposure light 10a emitted via the light source 10, the aperture diaphragm 11 and the filter 12.

The illumination optics 14 is configured by, for example, a fly-eye lens, a multi-stage capacitor lens or the like, and used for adjusting a range or the like of the exposure light 10a entering the photomask 6.

The projection optics 15 is used for reduction-projecting the mask pattern formed onto the photomask 6 on the resist film 8, so that it is configured by, for example, a plurality of lens such as lens 150, 151. Also, the projection optics 15 is capable of adjusting a position of pupil surface 152 by the lens 150, 151.

The lens diaphragm 16 is used for changing a shape of the exposure light 10a emitted from the lens 151. Namely, the lens diaphragm 16 is capable of shielding the exposure light 10a aside from a center axis of the projection optics 15 by changing largeness of the pupil of projection optics 15.

The processing device 3 is used for processing the resist film 8 exposed via the mask pattern. The processing includes processes except for a light exposure such as a dry etching process, a wet etching process (including a developing process), a film formation, an ion implant.

The measurement device 4 is used for, for example, measuring a finishing dimension of line width of the resist pattern formed onto the wafer 7. The measurement device 4 is configured to include, for example, an atomic force microscope (AFM), a scanning electron microscope (SEM) and the like.

As shown in FIG. 1, the control device 5 is roughly configured so as to include a control part 50, a memory part 51, a simulation part 52 and a calculation part 53.

The control part 50 is formed of, for example, a central processing unit (CPU), a read only memory (ROM), Random access memory (RAM) and the like, and it is used for controlling the light source 10, the aperture diaphragm 11, the filter 12, the polarization filter 13, the illumination optics 14, the projection optics 15 and the lens diaphragm 16 of the exposure device 2; the processing device 3; and the measurement device 4.

The memory part 51 is used for storing exposure parameter 510, control information 511, dimension distribution information 512 and simulation information 513.

The exposure parameter 510 includes, for example, information such a as exposure amount, defocus quantity, defocus range, light shape, light brightness distribution, light polarization state, lens numerical aperture, lens aberration, lens pupil surface transmittance distribution, and exposure laser wavelength band width.

The exposure amount is an amount adjustable by controlling the light source 10 of the exposure device 2, for example, a finished dimension of the resist pattern can be reduced than the designed dimension by increasing the exposure amount than a standard amount and the finished dimension of the resist pattern can be increased than the designed dimension by reducing the exposure amount than the standard amount. Here, the designed dimension means a line width of the resist pattern that is determined at the time of designing a semiconductor device. Also, the standard amount means an exposure amount that equalizes the finished dimension and the designed dimension.

The control information 511 includes, for example, information about a manufacturing process of the semiconductor device described below, control information about the processing device 3 and the measurement device, and the like.

The dimension distribution information 512 is, for example, information about measurement result of the measurement device 4, and includes information about a dimension distribution of the resist pattern formed onto the wafer 7 and the like.

The simulation information 513 includes, for example, information necessary for carrying out a simulation of the exposure device 2 and the processing device 3 and the like. The calculation part 53, for example, prepares the dimension distribution information 512 from the finished dimension measured, and calculates a target dimension described below from the dimension distribution information 512.

The photomask 6, for example, is obtained by forming a shielding film of metal such as chromium or a halftone film on a transparent substrate of silica glass or the like, and by forming a mask pattern on the shielding film.

FIG. 3 is an explanatory view schematically showing a wafer used in the first embodiment of the invention. The wafer 7 has a first resist pattern 80 formed for determining an exposure parameter.

The wafer 7 is formed of, for example, a silicon material.

The exposure shot 70 shows a minimum unit when the resist film 8 is exposed via a mask pattern described below. For example, six dies 71 formed onto the photomask 6 is reduction-projected in the exposure shot 70. Namely, the mask pattern is formed of, for example, a pattern obtained by enlarging the six dies 71.

The die 71 has, for example, a semiconductor integrated circuit pattern such as a semiconductor memory, and as shown in FIG. 3, it includes a fine pattern region 72, a peripheral circuit pattern region 73, and evaluation patterns 74, 75.

The fine pattern region 72 is, for example, a region constituting a memory cell, that includes a first projection pattern 720 having a line width of a minimum dimension in the die 71. The first projection pattern 720 is obtained, for example, by reduction-projecting a first pattern onto the wafer 7, the first pattern being a mask pattern having a line width of a minimum dimension formed onto the photomask 6. Processing such as etching process is carried out under conditions that the line width of first projection pattern 720 included in the fine pattern region 72 becomes a designed dimension in the whole region on the wafer 7. Further, as the first projection pattern 720, any pattern can be used, not limited to a mask pattern having a pattern of the minimum dimension in the die, for example, a pattern having a minimum exposure margin or the like can be used.

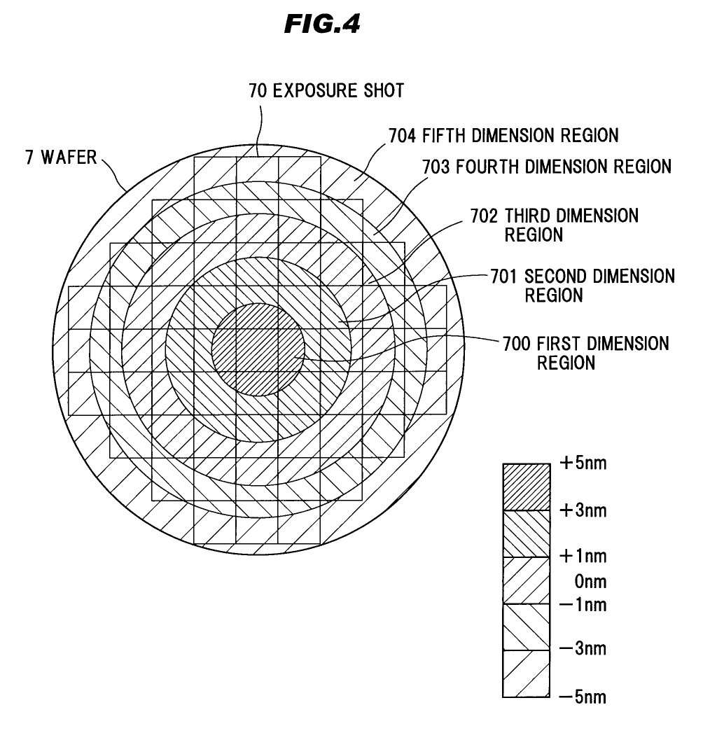

FIG. 4 is an explanatory view schematically showing a dimension distribution of a peripheral circuit pattern in the wafer used in the first embodiment of the invention. The peripheral circuit pattern region 73 is formed, for example, in a periphery of the memory cell, and it is a region that includes the second projection pattern 730 such as a sense amplifier amplifying electrical pressure from the memory cell having a line width thicker than the memory cell. The second projection pattern 730 is obtained, for example, by reduction-projecting a mask pattern (second pattern) onto the wafer 7, the second pattern having a dimension larger than a mask pattern (first pattern) having a line width of a minimum dimension in the photomask 6. Further, as the second projection pattern 730, any pattern can be used, and a pattern different from the first pattern can be also used.

As shown in FIG. 4, the peripheral circuit pattern region 73 has a finished dimension varying in a concentric shape, since processing such as etching process is carried out under conditions appropriate for the first projection pattern 720 included in the fine pattern region 72. Namely, the second projection pattern 730 included in the peripheral circuit pattern region 73 has a tendency for the line width to be thinned from the center toward the peripheral edge, and in first to fifth dimension regions 700 to 704, the line width varies from +5 nm to −5 nm.

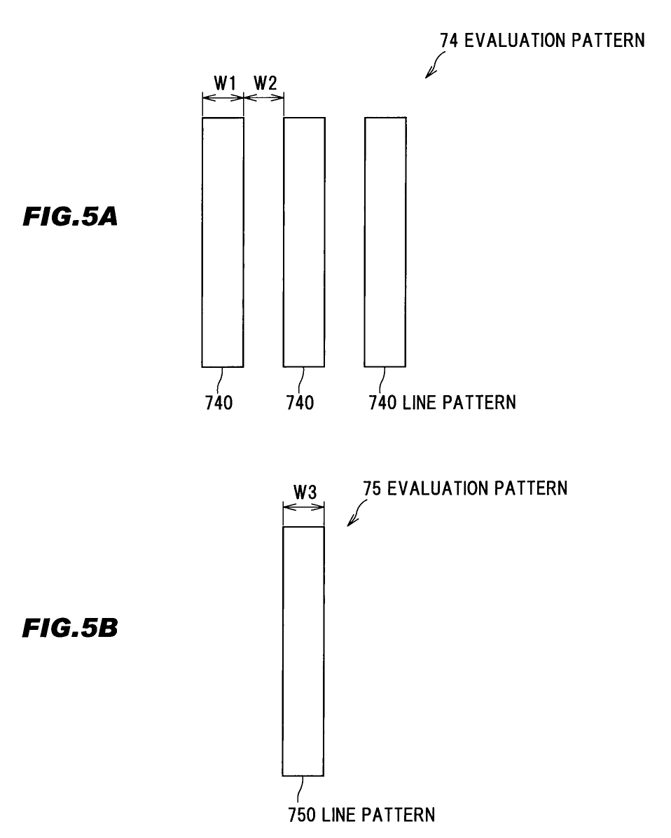

FIGS. 5A and 5B are explanatory views schematically showing an evaluation pattern used in the first embodiment of the invention. Evaluation patterns 74, 75 are patterns, for example, used for measuring a dimension of the resist pattern. Further, the patterns used for measuring the dimension of the resist pattern are not particularly limited to the evaluation patterns 74, 75, but patterns for manufacturing control or appropriate patterns extracted from the first and second projection patterns 720, 730 included in the fine pattern region 72 and the peripheral circuit pattern region 73 can be used, and patterns of circuit formed can be directly measured, further, the number of the pattern is not particularly limited.

As shown in FIG. 5A, the evaluation pattern 74 is formed, for example, in a periphery of the peripheral circuit pattern region 73 as closely-spaced patterns. The evaluation pattern 74 has a plurality of line patterns 740 of line width W1 arranged at intervals W2, so as to form a line and space pattern having a structure that a line pattern and a space pattern are repeated by turns. The evaluation pattern 74 in the embodiment is formed, as an example, so as to have the same line width of the minimum dimension as the first projection pattern 720. The measurement device 4 measures, for example, the line width W1.

As shown in FIG. 5B, the evaluation pattern 75 is formed, for example, in a periphery of the peripheral circuit pattern region 73 as an isolated pattern of a line pattern 750 of line width W3. The evaluation pattern 75 in the embodiment is formed, as an example, so as to have the line width similar to the second projection pattern 730. The measurement device 4 measures, for example, the line width W3.

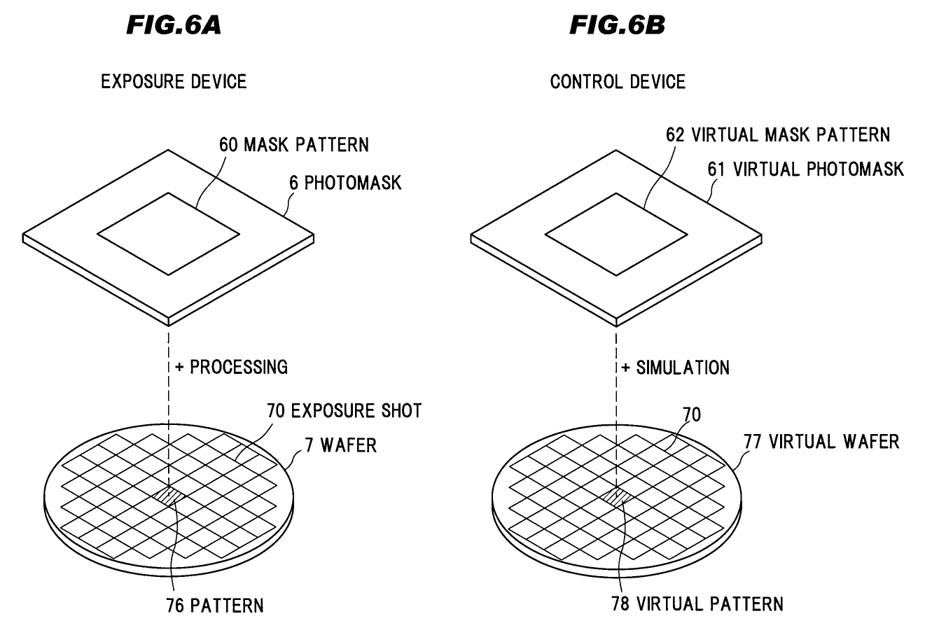

FIG. 6A is an explanatory view schematically showing a state of light exposure by an exposure device according to the first embodiment of the invention. FIG. 6B is an explanatory view schematically showing a state of simulation by a control device used in the first embodiment of the invention.

The simulation part 52 carries out simulations of a coating process of the resist material, an exposure process, a processing process and the like based on simulation information 513.

As shown in FIG. 6A, in the exposure device 2, a mask pattern 60 is reduction-projected on the resist film 8 and processing is carried out, so as to form a pattern 76. The measurement device measures a line width of the evaluation pattern 74 of the pattern 76 as a finished dimension of the first projection pattern 720 included in the fine pattern region 72, and a line width of the evaluation pattern 75 as a finished dimension of the second projection pattern 730 included in the peripheral circuit pattern region 73.

On the other hand, as shown in FIG. 6B, the simulation part 52 of the control device 5 carries out simulations of a virtual photomask 61 corresponding to the photomask 6, a virtual mask pattern 62 corresponding to the mask pattern 60, a virtual wafer 77 corresponding to the wafer 7, the resist film 8, the exposure device 2, the processing device and the like based on simulation information 513, so as to form a virtual pattern 78 onto the virtual wafer 77. The simulation part 52 measures a finished dimension of an evaluation pattern included in the virtual pattern 78.

(Method of Manufacturing Semiconductor Device)

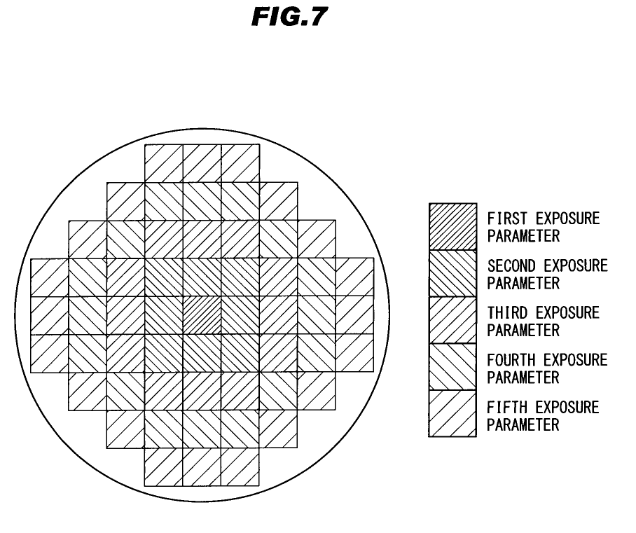

FIG. 7 is an explanatory view schematically showing a condition of light exposure used in the first embodiment of the invention.

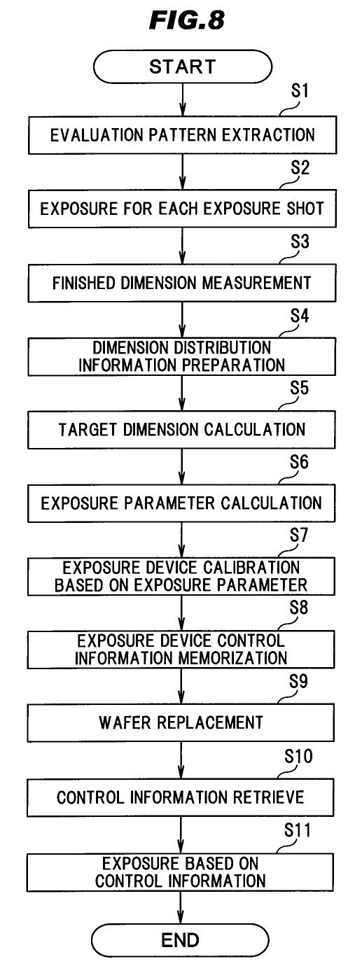

Hereinafter, an example of a method of manufacturing a semiconductor device according to the first embodiment will be explained, referring to the drawings, in accordance with a flowchart shown in FIG. 8.

First, the control part 50 of the control device 5 extracts the evaluation patterns 74, 75 from the mask pattern 60 formed onto the photomask 6 set to the exposure device 2 (S1).

Next, the control part 50 controls the light source 10 and the like, and carries out a plurality of shots onto the resist film 8 formed on the wafer 7 by using the first exposure parameter, where the first pattern formed onto the photomask 6 and the second pattern having a dimension larger than the first pattern are used as an exposure subject of one shot (S2).

Next, the control part 50 controls the processing device and carries out processing under conditions that are appropriate for the first projection pattern 720 included in the fine pattern region 72, namely, under conditions that allow a finished dimension of the first projection pattern 720 to be a designed dimension, so as to form a first resist pattern 80 on the wafer 7.

Next, the control part 50 controls the measurement device 4 so as to measure a finished dimension of the first resist pattern 80 with respect to each light exposure shot 70 (S3). Particularly, the measurement device 4 measures finished dimensions of the evaluation patterns 74, 75 with respect to each light exposure shot 70. Measurement result of the evaluation pattern 74 is used for confirming a finished dimension of the fine pattern region 72.

Next, the calculation part 53 prepares dimension distribution information 512 based on the finished dimension of the evaluation pattern 75 measured with respect to each light exposure shot 70 (S4).

Next, the calculation part 53 calculates a target exposure image dimension with respect to each light exposure shot 70 so that the finished dimension of the second projection pattern 730 included in the peripheral circuit pattern region 73 has a uniform dimension in the whole region of the wafer 7 based on the dimension distribution information 512 (S5).

The target exposure image dimension has a different value with respect to each light exposure shot 70 so that the second projection pattern 730 has a uniform dimension in the whole region of the wafer 7, even if the processing is carried out under conditions that are appropriate for the first projection pattern 720. For example, since the finished dimension of the second projection pattern 730 becomes, as an example, thicker by 5 nm to the light exposure shot 70 included in the first dimension region 700 (adjacent to the center of wafer 7) shown in FIG. 4, the target exposure image dimension is set so as to allow an image of the second projection pattern 730 of the mask pattern 60 due to the exposure to be thinned by 5 nm on the resist film 8.

Also, For example, since the finished dimension of the second projection pattern 730 becomes, as an example, thinner by 5 nm to the light exposure shot 70 included in the fifth dimension region 704 (adjacent to the peripheral edge of wafer 7) shown in FIG. 4, the target exposure image dimension is set so as to allow an image of the second projection pattern 730 of the mask pattern 60 due to the exposure to be thickened by 5 nm on the resist film 8.

Further, the target exposure image dimension can be determined, for example, due to an average amount of the six evaluation patterns 74 in the light exposure shot 70, or it can be also determined so that more dies 71 of the six dies 71 included in the light exposure shot 70 become good products.

Next, the simulation part 52 calculates an exposure parameter 510 as the second exposure parameter based on the target exposure image dimension with respect to each light exposure shot 70 (S6), so as to allow the memory part 51 to store via the control part 50. Further, the second exposure parameter is a parameter modified from the first exposure parameter as to any of defocus quantity, defocus range, light shape, light brightness distribution, light polarization state, lens numerical aperture, lens aberration, lens pupil surface transmittance distribution and exposure laser wavelength band width.

Particularly, the simulation part 52 determines the exposure parameter 510 as the second exposure parameter including exposure parameters except for the exposure amount in a plurality of regions to be shot in the surface of wafer 7 so that a resist pattern of the first resist pattern 80 formed based on the second pattern, namely, the second projection pattern 730 becomes to have a predetermined dimension. Here, the region to be shot means a region of the wafer 7 where light exposure is shot.

In other words, the simulation part 52 selects from defocus quantity, defocus range, light shape, light brightness distribution, light polarization state, lens numerical aperture, lens aberration, lens pupil surface transmittance distribution and exposure laser wavelength band width exposure amount and adjusts them, for example, to the light exposure shot 70 included in the first dimension region 700, so as to allow an image of the second projection pattern 730 of the mask pattern 60 due to the exposure to be thinned by 5 nm on the resist film 8 and to allow the finished dimension of the first projection pattern 720 not to be changed. Further, the simulation part is conditioned not to allow the exposure amount to independently vary when the exposure parameter 510 is calculated, due to the fact that the dimension of the first projection pattern 720 varies.

The exposure parameter 510 determined as described above varies in the exposure parameters, for example, in a concentric shape as the first to fifth exposure parameter shown in FIG. 7, since the finished dimension of the second projection pattern 730 has a tendency to vary in a concentric shape.

Next, the control part 50 carries out calibration with respect to each light exposure shot 70 based on the exposure parameter 510 (S7).

Next, the control part 50 allows the calibration with respect to each light exposure shot 70 to be stored in the memory part 51 as the control information 511 (S8).

Next, the exposure device 2 replaces the wafer 7 (S9).

Next, the control part 50 retrieves the control information 511 from the memory part 51 (S10), and controls the light source 10 and the like of the exposure device 2 based on the exposure parameter 510 with respect to each light exposure shot 70, and the exposure device 2 carries out an light exposure (S11).

Particularly, the control part 50 carries out a plurality of shots onto the resist film 8 formed on the wafer 7 replaced by using the exposure parameter 510 as the second exposure parameter, where the first and second patterns are used as an exposure subject of one shot. Namely, as shown in FIG. 7, the control part 50 carries out the light exposure while the first to fifth exposure parameters are varied in order from the center to the peripheral edge.

After completion of the light exposure, a second resist pattern is formed by using the same processing condition as the processing condition under which the resist pattern 80 is formed, and via well-known processes, a semiconductor device is manufactured.

Further, the method of manufacturing a semiconductor device according to the embodiment is not particularly limited to the above-mentioned process order. For example, the process of exchanging the wafer in Step 6 (S6) can be carried out before or after any of Step 7 (S7) and Step 10 (S10), and can be also carried out in parallel to any of Step 7 (S7) and Step 10 (S10).

Also, in the process of determining the second exposure parameter, only when the regions to be shot are subjected to the exposure shot, the second exposure parameter can be determined and a shot can be carried out by using the second exposure parameter determined, the regions to be shot having an error between a dimension of the resist pattern of the first resist pattern 80 formed based on the second pattern, namely a dimension of the second projection pattern 730, and a designed value, the error being not less than a predetermined value.

### Advantages of First Embodiment

1. According to a method of manufacturing a semiconductor device and an exposure device in the embodiment, the following advantages can be obtained.

The light exposure is carried out while the exposure parameter 510 is varied with respect to each light exposure shot 70, so that not only the finished dimension of the first projection pattern 720 included in the fine pattern region 72 but also the finished dimension of the second projection pattern 730 included in the peripheral circuit pattern region 73 can have a uniform dimension in the whole region of the wafer 7 under the same conditions.

2. Variation of the finished dimension of the second projection pattern 730 can be more accurately corrected in comparison with a method that corrects a dimension by independently adjusting an exposure amount.

### Second Embodiment

A second embodiment is different from the first embodiment in that an exposure parameter is calculated as to the top wafer in lot, and as to the wafers that follow the top wafer in lot, a light exposure is carried out by using the exposure parameter calculated as to the top wafer. Further, in the following embodiments, with regard to elements having the same construction and function as the first embodiment, the same references as the first embodiment will be used, and detail explanation will be omitted.

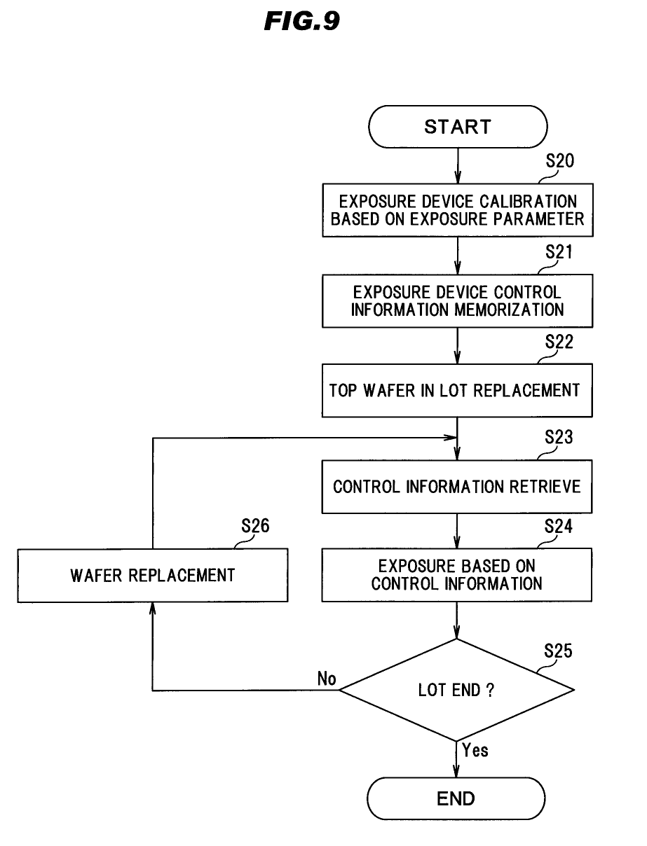

Hereinafter, a method of manufacturing a semiconductor device according to the second embodiment will be explained referring to the drawings and according to a flowchart shown in FIG. 9. Further, a lot means a production unit grouped for administrating the wafers or a production unit in case of producing a group of the same type of products.

First, a substrate processing system 1 carries out processes of Step 1 (S1) to Step 6 (S6) in the first embodiment as to the top wafer in lot so as to calculate an exposure parameter 510 and store the exposure parameter 510 in the memory part 51.

Next, the control part 50 retrieves the exposure parameter 510 stored in the memory part 51 and calibration with respect to each light exposure shot 70 is carried out based on the exposure parameter 510 retrieved (S20).

Next, the control part 50 allows the memory part 51 to store the calibration with respect to each light exposure shot 70 as the control information 511 (S21).

Next, the exposure device 2 replaces the top wafer 7 in lot and sets a new wafer (S22).

Next, the control part 50 retrieves the control information 511 from the memory part 51 (S23), and controls the exposure device 2 based on the exposure parameter 510 with respect to each light exposure shot 70, and the exposure device 2 carries out a light exposure (S24).

Next, if the wafer exposed is not the last wafer of lot (S25: No), the control part 50 controls the exposure device 2 to replace the wafer to a new wafer (S26), returning to Step 23 (S23), a light exposure is carried out to the replaced wafer. Subsequently, the control part 50 completes the exposure process, if Yes in Step 25 (S25), namely, when the light exposure of the last wafer of lot is completed.

### Advantages of Second Embodiment

According to a method of manufacturing a semiconductor device and an exposure device in the embodiment, the exposure parameter 510 is calculated from the top wafer in lot, and as to the wafers that follow the top wafer in lot, the light exposure is carried out based on the exposure parameter 510 so that reduction in throughput can be prevented.

### Third Embodiment

A third embodiment is different from the first and second embodiments in that the exposure parameter is varied as to only the exposure shots forming a finished dimension of not less than a threshold value in comparison with adjacent exposure shots, instead that the exposure parameter is varied as to all of the light exposure shots.

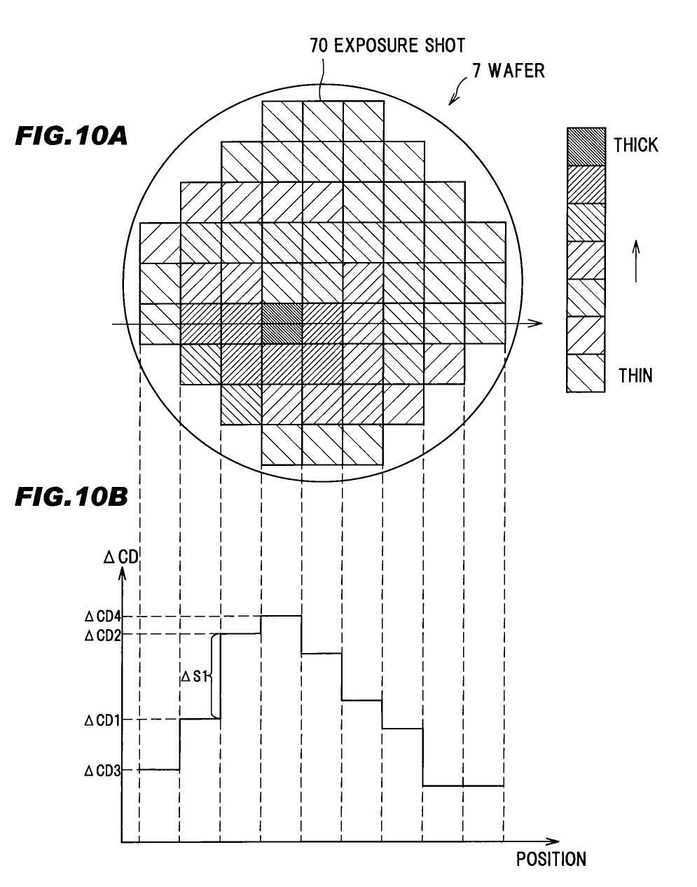

FIG. 10A is an explanatory view schematically showing a dimension distribution with respect to each light exposure shot used in a third embodiment of the invention. FIG. 10B is a graph schematically showing a dimension difference ΔCD of the light exposure shot passing through a region indicated by an arrowed line in FIG. 10A. FIG. 10A shows that a finished dimension of a pattern becomes thick as an interval between diagonal lines becomes narrow. In FIG. 10B, a longitudinal axis shows dimension difference ΔCD (a finished dimension—a designed dimension), and a horizontal axis corresponds to a position on the wafer.

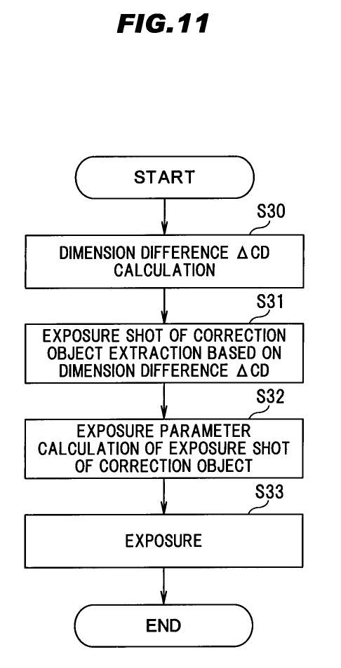

Hereinafter, a method of manufacturing a semiconductor device according to the third embodiment will be explained referring to the drawings and according to a flowchart shown in FIG. 11.

First, processes of Step 1 (S1) to Step 4 (S4) in the first embodiment are carried out so as to prepare dimension distribution information 512.

Next, the calculation part 53 calculates a dimension difference ΔCD between a finished dimension of the evaluation pattern 75 and a designed dimension based on the dimension distribution information 512 (S30).

As shown in FIGS. 10A and 10B, the control part 50 extracts an exposure shot 70 of correction subject based on the dimension difference ΔCD (S31).

Particularly, the control part 50 extracts the exposure shot 70 having a difference ΔS between the dimension difference ΔCD of exposure shot 70 and the dimension difference ΔCD of the adjacent exposure shot 70, the difference ΔS being larger than the threshold value. Further, the difference ΔS is sequentially calculated, for example, from the exposure shot 70 located at the upper left of the wafer 7 shown in FIG. 10A to the exposure shot 70 adjacent in a right direction, subsequently, the difference ΔS is calculated from the upper left to the lower left step by step. FIG. 10B shows the difference ΔS between the exposure shots 70 where the arrow passes through, but it can be also adopted that each difference ΔS between four exposure shots 70 adjacent to each other is calculated and the largest one of these differences ΔS is determined as the difference ΔS, or each difference ΔS between eight exposure shots 70 located around is calculated and the largest one of these differences ΔS is determined as the difference ΔS. The threshold value is a preset value and it is stored in the memory part 51.

As shown in FIG. 10B, the calculation part 53 calculates an absolute value of a difference between dimensional differences ΔCD adjacent to each other |ΔCD2-ΔCD1| so as to calculate the difference ΔS1. Subsequently, the calculation part 53 calculates the difference ΔS between the other exposure shots 70. The control part 50 compares the difference ΔS calculated with the threshold value. The control part 50, for example, when it determines that the difference ΔS1 shown in FIG. 10B is larger than the threshold value, determines to choose one from two exposure shots 70 as a correction subject, one exposure shot 70 having the dimensional differences ΔCD1 shown in FIG. 10B and another exposure shot 70 having the dimensional differences ΔCD2.

Particularly, the determination is carried out, for example, so as to choose one having the dimensional difference ΔCD larger than another as the correction subject, choose one having the dimensional difference ΔCD between adjacent exposure shots larger than another as the correction subject or choose both of two exposure shots as the correction subject.

In case of choosing one having the dimensional difference ΔCD larger than another as the correction subject, as shown in FIG. 10B, the dimensional difference ΔCD2 is larger than the dimensional difference ΔCD1 so that the exposure shot having the dimensional difference ΔCD2 is chosen as the correction subject.

Also, in case of choosing one having the dimensional difference ΔCD between adjacent exposure shots larger than another as the correction subject, the dimensional difference ΔCD4 of the exposure shot adjacent to the exposure shot having the dimensional difference ΔCD2 is larger than the dimensional difference ΔCD3 of the exposure shot adjacent to the exposure shot having the dimensional difference ΔCD1 so that the exposure shot having the dimensional difference ΔCD2 is chosen as the correction subject.

Further, in case of choosing both of two exposure shots as the correction subject, both of the exposure shot having the dimensional difference ΔCD1 and the exposure shot having the dimensional difference ΔCD2 are chosen as the correction subject.

Next, the calculation part 53 calculates an exposure parameter 510 of the exposure shot of the correction subject (for example, the exposure shot having the dimensional difference ΔCD1) (S32). Particularly, the calculation part 53 calculates a target dimension of the exposure shot having the dimensional difference ΔCD1, and carries out the process of Step 6 (S6) in the first embodiment so as to calculate an exposure parameter 510. The target dimension can be, for example, an average of the finished dimensions of the whole wafer, a designed dimension or an average of the finished dimensions of the exposure shots adjacent to the exposure shot of the correction subject, not particularly limited to these.

Next, the processes of Step 7 (S7) and Step 8 (S8) in the first embodiment are carried out, and the exposure device 2 replaces the wafer and sets a new wafer.

Next, the control part 50 retrieves the control information 511 from the memory part 51 and carries out a light exposure (S33). Particularly, the control part 50 applies a light exposure to a new wafer by using the exposure parameter as to the pre-replacement wafer, and as to the post-replacement wafer, it applies a light exposure to exposure shots corresponding to the exposure shots of correction subject based on the exposure parameter 510 calculated in Step 32.

### Advantages of Third Embodiment

According to a method of manufacturing a semiconductor device and an exposure device in the embodiment, the exposure parameter 510 is calculated as to only the exposure shots of correction subject and the light exposure is applied to only the exposure shots of correction subject, so that throughput can be enhanced in comparison with a case of carrying out a light exposure while the exposure parameter is varied with respect to each light exposure shot.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

For example, the exposure parameter 510 is calculated by the simulation part 52 in each of the above-mentioned embodiments, but not particularly limited to this, the exposure parameter 510 can be determined by experiment.

What is claimed is:

1. A method of manufacturing a semiconductor device, comprising:
carrying out a plurality of shots to a resist film formed on a wafer by using a first exposure parameter, wherein a first pattern and a second pattern having a dimension larger than the first pattern are used as an exposure subject of one shot;
carrying out a processing of the resist film by using a processing condition that a resist pattern formed based on the first pattern has a desired dimension when the resist film is fabricated, so as to form a first resist pattern;
measuring a dimension of a resist pattern of the first resist pattern, the resist pattern being formed based on the second pattern, so as to prepare dimension distribution information within a surface of the wafer;
determining a second exposure parameter including exposure parameters except for an exposure amount from the dimension distribution information so that the resist pattern of the first resist pattern formed based on the second pattern has a desired dimension in a plurality of regions to be shot within the surface of the wafer;
carrying out a plurality of shots to the resist film formed onto the wafer by using a second exposure parameter, wherein the first pattern and the second pattern are used as the exposure subject of one shot; and
fabricating the resist film under the processing condition so as to form a second resist pattern.

2. The method of manufacturing a semiconductor device according to claim 1, wherein the second exposure parameter includes the exposure parameters varying as they are far away from the center of wafer, in the regions to be shot arranged in a concentric shape from the center of wafer.

3. The method of manufacturing a semiconductor device according to claim 2, wherein the second exposure parameter is determined as to the top wafer in lot.

4. The method of manufacturing a semiconductor device according to claim 3, wherein the plural shots by using the second exposure parameter are carried out as to the wafers that follow the top wafer in lot.

5. The method of manufacturing a semiconductor device according to claim 4, wherein the second exposure parameter is determined as to the regions to be shot where an error between a dimension of the resist pattern formed based on the second pattern of the first resist pattern and a design value is not less than a desired value.

6. The method of manufacturing a semiconductor device according to claim 5, wherein the first pattern is a fine pattern constituting a memory cell, and
the second pattern is a peripheral circuit pattern formed in a periphery of the memory cell.

7. The method of manufacturing a semiconductor device according to claim 6, wherein the second exposure parameter is a parameter modified from the first exposure parameter as to any of defocus quantity, defocus range, light shape, light brightness distribution, light polarization state, lens numerical aperture, lens aberration, lens pupil surface transmittance distribution and exposure laser wavelength band width.

8. The method of manufacturing a semiconductor device according to claim 7, wherein the first pattern includes a line and space pattern having a structure that a line pattern and a space pattern are repeated by turns.

9. The method of manufacturing a semiconductor device according to claim 1, wherein the second exposure parameter is determined as to the region to be shot where an absolute value of dimension difference between the exposure shots adjacent to each other is larger than a threshold value.

10. The method of manufacturing a semiconductor device according to claim 9, wherein the second exposure parameter is a parameter modified from the first exposure parameter as to any of defocus quantity, defocus range, light shape, light brightness distribution, light polarization state, lens numerical aperture, lens aberration, lens pupil surface transmittance distribution and exposure laser wavelength band width.

11. An exposure device, comprising:
an exposure parameter determination part for determining a second exposure parameter including exposure parameters except for an exposure amount, wherein the exposure parameter determination part has the functions of carrying out a plurality of shots to a resist film formed on a wafer by using a first exposure parameter, wherein a first pattern and a second pattern having a dimension larger than the first pattern are used as an exposure subject of one shot, carrying out a processing of the resist film by using a processing condition that a resist pattern formed based on the first pattern has a desired dimension when the resist film is fabricated, so as to form a first resist pattern, measuring a dimension of a resist pattern of the first resist pattern, the resist pattern being formed based on the second pattern, so as to prepare dimension distribution information within a surface of the wafer, and determining a second exposure parameter including exposure parameters except for an exposure amount from the dimension distribution information so that the resist pattern of the first resist pattern formed based on the second pattern has a desired dimension in a plurality of regions to be shot within the surface of the wafer.

12. The exposure device according to claim 11, wherein the exposure parameter determination part determines the second exposure parameters varying as they are far away from the center of wafer, in the regions to be shot arranged in a concentric shape from the center of wafer.

13. The exposure device according to claim 12, wherein the exposure parameter determination part determines the second exposure parameter as to the top wafer in lot.

14. The exposure device according to claim 13, wherein the plural shots by using the second exposure parameter are carried out as to the wafers that follow the top wafer in lot.

15. The exposure device according to claim 14, wherein the exposure parameter determination part determines the second exposure parameter in the regions to be shot where an error between a dimension of the resist pattern firmed based on the second pattern of the first resist pattern and a design value is not less than a desired value.

16. The exposure device according to claim 15, wherein the first pattern is a fine pattern constituting a memory cell, and the second pattern is a peripheral circuit pattern formed in a periphery of the memory cell.

17. The exposure device according to claim 16, wherein the second exposure parameter is a parameter modified from the first exposure parameter as to any of defocus quantity, defocus range, light shape, light brightness distribution, light polarization state, lens numerical aperture, lens aberration, lens pupil surface transmittance distribution and exposure laser wavelength band width.

18. The exposure device according to claim 17, wherein the first pattern includes a line and space pattern having a structure that a line pattern and a space pattern are repeated by turns.

19. The exposure device according to claim 11, wherein the exposure parameter determination part determines the second exposure parameter in the region to be shot where an absolute value of dimension difference between the exposure shots adjacent to each other is larger than a threshold value.

20. The exposure device according to claim 19, wherein the second exposure parameter is a parameter modified from the first exposure parameter as to any of defocus quantity, defocus range, light shape, light brightness distribution, light polarization state, lens numerical aperture, lens aberration, lens pupil surface transmittance distribution and exposure laser wavelength band width.
